(19) United States
(12) Patent Application Publication
(10) Pub. No.: US 2007/0167029 A1
(43) Pub. Date: Jul. 19, 2007

(54) THERMAL PROCESSING SYSTEM, COMPONENTS, AND METHODS

(76) Inventors: Jeffrey Michael Kowalski, Aptos, CA (US); Jeffrey Edward Kowalski, San Jose, CA (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/559,315

(22) Filed: Nov. 13, 2006

Related U.S. Application Data
(60) Provisional application No. 60/735,382, filed on Nov. 11, 2005.

(51) Int. Cl. H01L 21/31

(52) U.S. Cl. 438/769

(57) ABSTRACT

Thermal treatment is an important process in the manufacture of integrated circuits. As integrated circuits evolve to become smaller and faster, there is an increasing need to for higher precision thermal treatment systems that can efficiently and uniformly heat these circuits without damaging them. Accordingly, the present inventors devised, among other things, an exemplary thermal treatment system that includes a microwave-reflective containment chamber, an inner microwave-transparent process chamber within the containment chamber, a microwave-transparent wafer carrier within the process chamber; and a 5.8 Gigahertz microwave source for introducing microwave radiation within the outer chamber. The system can be used to efficiently oxidize a batch of vertically stacked of silicon wafers using a 10% concentration of ozone.

### RELATED APPLICATION

The present application claims priority to U.S. Provisional Patent Application 60/735,382, which was filed on Nov. 11, 2005 and which is incorporated herein by reference.

### COPYRIGHT NOTICE AND PERMISSION

A portion of this patent document contains material subject to copyright protection. The copyright owner has no objection to the facsimile reproduction by anyone of the patent document or the patent disclosure, as it appears in the Patent and Trademark Office patent files or records, but otherwise reserves all copyrights whatsoever. The following notice applies to this document: Copyright© 2005, DSG Technologies.

### TECHNICAL FIELD

Various embodiments of the present invention concern the manufacture of integrated circuits, particularly systems, devices, and methods for heating wafers, integrated circuit assemblies, and related components.

### BACKGROUND

Integrated circuits, the key components in thousands of electronic and computer products, are interconnected networks of electrical components fabricated on a common foundation, or substrate. Fabricators generally build these circuits layer by layer, using techniques, such as deposition, doping, masking, and etching, to form and interconnect thousands, millions, or even billions of microscopic transistors, resistors, and other electrical components on a substrate, known as a wafer. The wafer typically consists of a semiconductor material, such as silicon.

Of the wide variety of techniques that are used to make integrated circuits, one of the most prevalent is thermal treatment. The technique generally entails placing one or more wafers (or integrated circuit assemblies) in a single, closed, infrared heating chamber, injecting inert or reactive gases into the chamber at specific pressures, and then heating the gases and wafers to specific temperatures. In some cases, the gases may react with each other and/or the wafer surfaces to form desirable films, such as silicon oxide. In others, the heating effectively cures various portions of the wafers, such as metallic structures. Effective thermal treatment sometimes entails not only elevating the wafer to a particular temperature, but also cycling the wafer between temperature extremes.

Although conventional thermal treatment systems have been effective for integrated circuits having features as small as 65 nanometers, the present inventors have recognized that treating wafers with smaller and faster circuitry pose at least two problems for these systems.

First, these smaller and faster integrated circuits include low-melting-point materials, such as nickel silicide, that melt at temperatures greater than 400 C Yet, conventional systems are not practical below 650 C because these temperatures fall below the radiation band where conventional resistance heating is efficient.

Second, with smaller features and more intricate geometries (such as trenches with aspect (width-to-height) ratios of 30:1), it is increasingly important to avoid non-uniform heating that creates relative hot and cold spots in and across the wafers. These spots are problematic because they induce mechanical stresses and strains, which in turn destroy the intricate features of the wafers. However, conventional systems heat wafers from the outside to the inside, relying on heat to travel or propagate from the outer surfaces of wafers to interior portions. This outside-in heat transfer is inherently non-uniform and thus causes mechanical stresses that can damage the delicate features of smaller and faster integrated circuitry.

In partial response to these problems, some manufactures have developed rapid thermal processing (RTP) chambers that treat wafers one at a time. Although the RTP chambers provide more uniform and faster heating than conventional batch heating chambers, the uniformity and rapidity are still less than desirable. Moreover, the inability to heat batches of wafers simultaneously slows down the processing of wafers, not only increasing the cost of making faster integrated circuits, but raising the cost of owning the equipment.

Accordingly, the present inventors have recognized a need for alternative systems and methods of thermally treating wafers.

### SUMMARY

To address these and/or other needs, the present inventors devised, among other things, thermal treatment systems, components, and methods, some of which provide rapid and substantially uniform heating and cooling of integrated circuit wafers and assemblies. One exemplary system includes an outer chamber of low bulk resistivity for reflecting and containing 0.9 GHz -28 GHz microwave energy, an inner microwave-transparent chamber within the outer chamber, and a microwave-transparent wafer carrier within the inner chamber. The exemplary wafer carrier is configured to carry a vertical microwave-absorbent stack of silicon wafers which not only have fixed physical geometry, but also known heating and dielectric characteristics.

In operation, the exemplary system uniformly heats the vertical stack, with reduced occurrence of hot spots and arcing associated with known uses of microwave. More specifically, the outer chamber, which for example takes form of a right octagonal cylinder, not only contains and reduces the microwave power required to heat circular wafers, but evenly distributes the microwaves over the vertical stack of wafers. Microwaves heat the wafers at the molecular level, from the inside out, enhancing thermal treatment uniformity across each wafer as well as across the stack. Additionally, stacking the wafers allows the wafers above and below any other wafer to serve as virtual hot plates that further promote uniform heating across each wafer. The virtual hot plates also serve as susceptor plates, promoting uniform power dissipation between wafers. (Some embodiment may stack or place other microwave-absorbing objects, such as silicon carbide plates or structures, between wafers to achieve similar effects.)

Moreover, because the outer chamber walls are microwave reflective and the inner chamber walls and wafer carrier are microwave transparent, the system effectively heats the wafers only. This means that the exemplary system has low thermal mass, in some cases 90% less than that of conventional resistance heating chambers, which allows not only rapid, uniform heating and temperature stabilization, but also rapid cooling. In some cases, cooling may be as much as 50 times faster than convention batch heating.

Other embodiments include other enhancements to reduce hotspots and arcing and to promote uniform heating. For example, some embodiments use higher frequency microwave energy (>2.45 GHz) reduces the wavelength of the microwave energy which in turn reduces the size of standing waves and facilitates management of electromagnetic power uniformity. Some embodiments vary the frequency of the microwave energy +/−1% relative to its nominal center frequency, whereas others vary the frequency more drastically, for example, by +/−5, 10, 20, or an even greater percentage. And still other embodiments place microwave absorbent material under or proximate each silicon wafer to further promote even distribution of microwave energy around each silicon wafer.

These and/or other embodiments are described below with aid of the following drawings.

### BRIEF DESCRIPTION OF THE DRAWINGS

FIG. 1A is a vertical cross-sectional block diagram of an exemplary thermal processing system 100 that corresponds to one or more embodiments of the present invention.

FIG. 1B is a top cross-sectional view of a portion of system 100 that corresponds to one or more embodiments of the present invention.

FIG. 1C is a partial perspective view of system 100 that corresponds to one or more embodiments of the invention.

FIG. 1D is a perspective view of a wafer stack assembly 132 in system 100, which corresponds to one or more embodiments of the present invention.

FIG. 1E is simplified block diagram of a system 100, illustrating control of some aspects of system 100 and thus corresponding to one or more embodiments of the present invention.

FIG. 2 is a flow chart of an exemplary method of operating system 100 that corresponds to one or more embodiments of the present invention.

FIG. 3 is a representation of microwave power distributions in three stacked wafers within system 100, which correspond to one or more embodiments of the present invention.

FIG. 4 is a graph of oxide thickness versus time for several process temperatures, which corresponds to one or more embodiments of the present invention.

### DETAILED DESCRIPTION OF EXEMPLARY EMBODIMENT(S)

This document describes one or more specific embodiments of an invention. These embodiments, offered not to limit but only to exemplify and teach the invention, are shown and described in sufficient detail to enable those skilled in the art to implement or practice the invention. Thus, where appropriate to avoid obscuring the invention, the description may omit certain information known to those of skill in the art.

### Exemplary Thermal Processing System

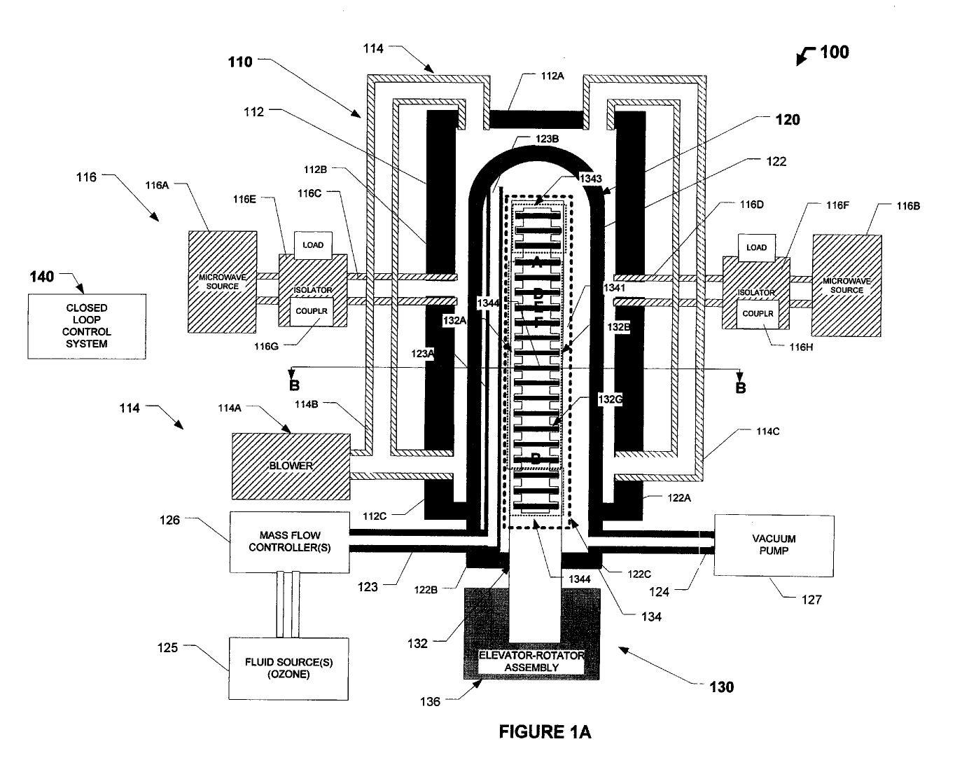

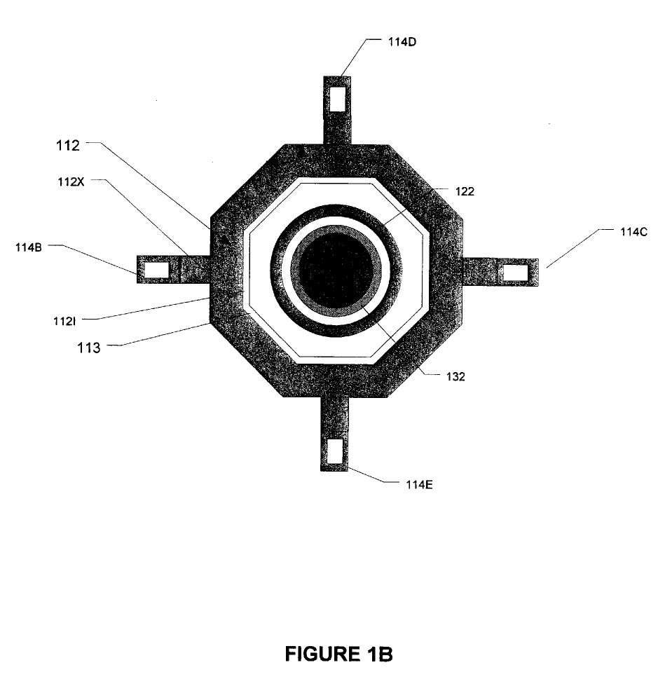

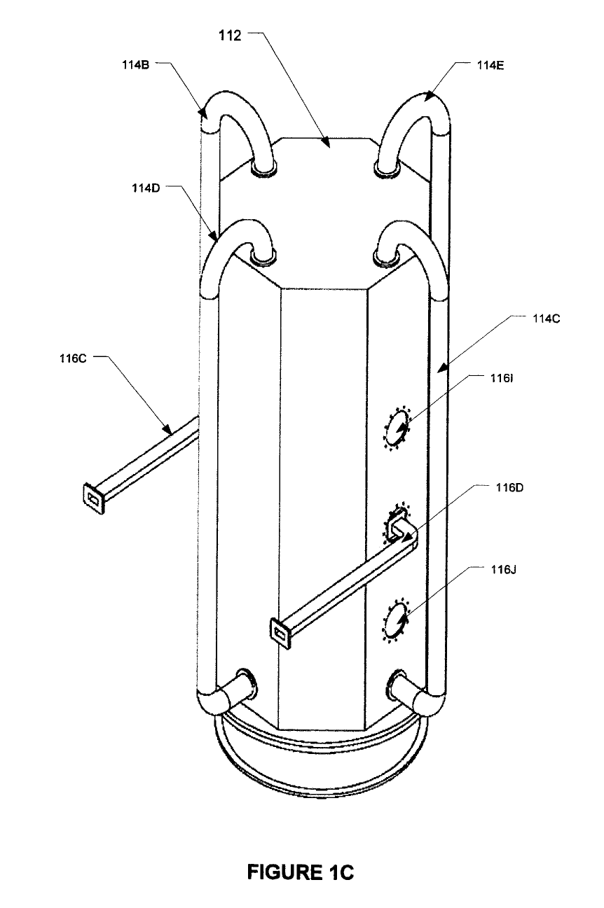

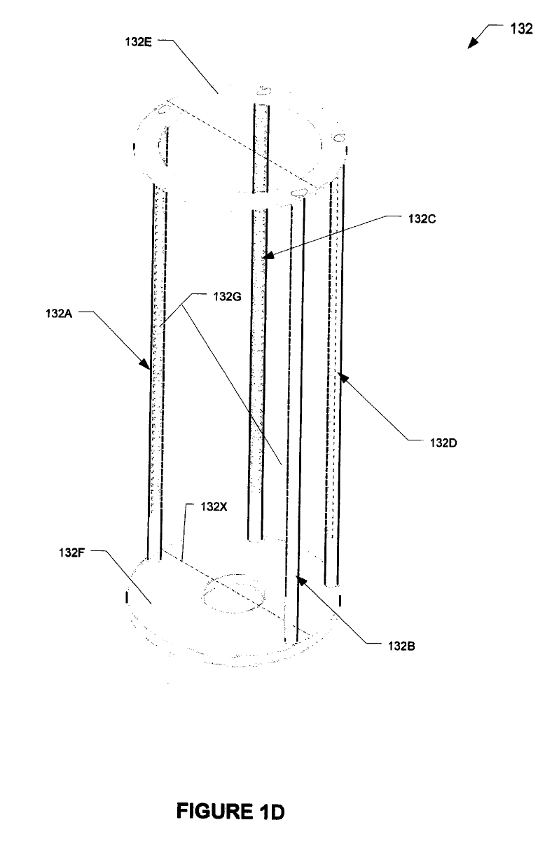

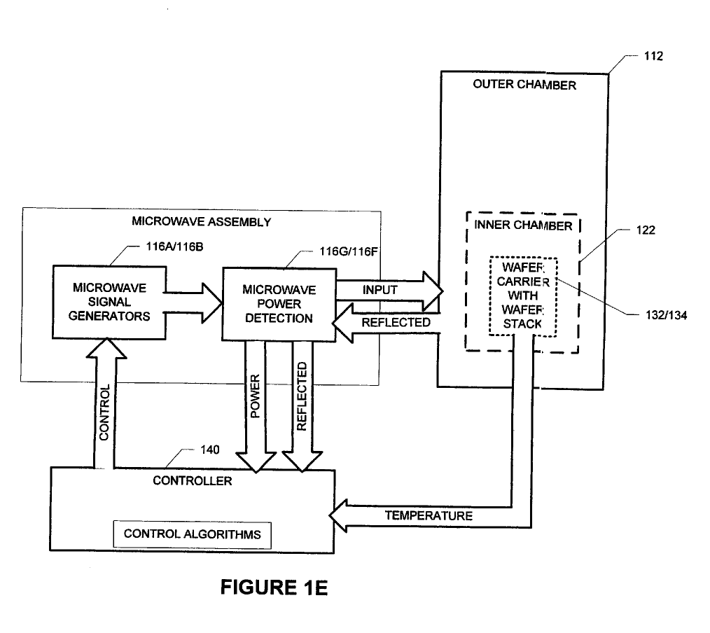

FIG. 1A and 1B show an exemplary thermal processing system 100. FIG. 1A is a longitudinal cross-sectional diagram of system 100, and FIG. 1B shows a top sectional view taken along a horizontal plane defined by line B-B in FIG. 1A. System 100 includes an outer chamber assembly 110, an inner chamber assembly 120, a wafer carrier assembly 130, and a controller 140.

Outer chamber assembly 110 includes an outer chamber 112, recirculating assembly 114, microwave generator assembly 116, and base assembly 118. In the exemplary embodiment, outer chamber 112, which takes the form of an octagonal right aluminum cylinder, includes a top portion 112A, a bottom portion 112B, and a middle portion 112C. Exemplary height and diameter of the octagonal cylinder are respectively 37.5 and 21 inches (or 0.953 and 0.544 meters.) Additionally outer chamber 112 includes an exterior surface 112X and an interior surface 112I, shown only in FIG. 1B for sake of clarity. FIG. 1C shows a partial perspective view of system 100, emphasizing outer chamber 112. (Some embodiment may clad outer chamber 112 within a housing to change the distinctive outward appearance of the system or incorporate additional shielding.)

Interior surface 112I has a reflective coating 113 consisting essentially of iridite or other material of low bulk resistivity and suitable for reflecting and containing the electromagnetic energy. Other suitable materials include copper, silver, aluminum, and stainless steel. Iridite enhances the reflective characteristic of the base material. Some embodiments may use a suitably coated high bulk resistivity material, such as plastic.

The exemplary octagonal chamber geometry effectively addresses two conflicting concerns: one is to reduce power requirements and thus mitigate arcing generally characteristic of microwave heating; and the other is to evenly distribute microwave energy throughout the chamber and thus promote uniform heating. From the standpoint of reducing power requirements and the related risk of arcing, a chamber with a circular footprint (plan view) is ideal for circular wafers, because it reduces the cavity or chamber volume and thus requires lower power levels to heat a given object to a specific temperature (assuming all other factors are equal.) However, a chamber with a circular footprint is ineffective at evenly distributing microwave energy. A square or rectangular chamber, on the other hand, has parallel walls with reflective properties that are considered ideal for promoting uniform energy distribution and thus uniform heating. Thus, the octagonal chamber effectively combines the power distribution advantages of square or rectangular chambers with the arcing-reduction aspects of a circular chamber.

Other embodiments use other geometries, for example, even-numbered polygons such as hexagons or decagons. Although the exemplary embodiment forms the outer chamber from aluminum, some embodiments may use other materials that are resistant to ohmic heating.

Outer chamber 112 is in fluid communication with recirculation assembly 114 and microwave generator assembly 116.

Recirculation assembly 114 recirculates and/or injects cool air in the region between outer chamber 112 and inner chamber 120, preventing convective currents from causing any significant temperature differential between the upper and lower portions of the chamber and thus further promoting uniform thermal treatment of wafers. Specifically, assembly 114 includes blower 114A, ducts 114B, 114C, 114D, and 114E. (Ducts 114D and 114E are not visible in FIG. 1A, but are shown in FIG. 1B and 1C.) Blower 114A is in fluid communication with ducts 114B-114E. (Some embodiments provide multiple blowers, for example, one for each duct or one for each pair of ducts.)

Ducts 114B-114E are substantially equilength and substantially equispaced around the perimeter of outer chamber 112, with ducts 114B and 114D positioned directly opposite respective ducts 114C and 114E. Each duct, which is formed of stainless steel tubing in the exemplary embodiment, extends approximately the height of chamber 112, providing fluid communication between corresponding openings in top portion 112A and bottom portion 112B of chamber 112. In some embodiments, ducts 114B-114E may include exterior fins or other structures to facilitate heat transfer to the ambient atmosphere. Additionally, other embodiments may include more or less ducts than the four in the exemplary embodiment.

Microwave signal generator assembly 116 includes microwave signal generators (or sources) 116A and 116B, wave guides 116C and 116D, and isolation units 116E and 116F. Microwave signal generator 116A includes one or more 0.90- GHz-28 GHz signal generators, such as magnetrons, gyrotrons, klystron tubes, or traveling wave tube amplifiers. The exemplary embodiment provides four 700-watt 5.8-GHz fixed-frequency magnetrons, coupling a vertically stacked pair of magnetrons on one side of the outer chamber, and another vertically stacked pair on the opposite side. In this embodiment, the output of each magnetron is coupled to outer chamber 112 at separate ports. One pair of ports is positioned on opposing sides of the outer chamber 12.75 inches (0.324 m) from the bottom of the chamber, and the other pair is positioned on the same opposing sides as the first pair, but 25 inches (0.635 m) from the bottom. (FIG. 1C shows wave guides 116C and 116D, as well as ports 116I and 116J for coupling to other wave guides and microwave signal generators.)

Simultaneous or otherwise synchronized introduction of microwave energy into the outer chamber through multiple ports promotes uniform power distribution throughout the chamber, thus reducing or minimizing the risk of arcing and further promoting uniform heating. A multi-source, multi-port arrangement also allows for independently varying the power levels and/or output frequencies of the sources for more complex control of power distribution. For instance, one can dynamically determine using temperature measurements that wafers in an upper or lower region are not hot enough and dynamically increase the power concentration in that region by adjusting output frequency and/or amplitude of the closest microwave sources. However, some embodiments may use a single source with a single port or a single source with multiple ports or even multiple sources with a single port.

The exemplary embodiment powers the 5.8 GHz magnetrons using commercially available switch-mode power supply, such as the CM 340 or CM440 power supply manufactured by Alter Power Systems of Italy (Alter S.R.L. a limited liability company, of ITALY), and thus provides a continuous wave of microwave power ranging from 0 to 700 watts based on the power setting. This allows one to limit the power levels in the chamber to heat the wafer to the desired temperature, thus reducing risk of arcing. With the switch-mode power supply at half voltage, the magnetrons can output 50% of their power continuously (for example, at 350 watts for a 700-watt maximum rated magnetron).

Also, the exemplary embodiment omits any filtration of the AC-input power to the power supply to allow oscillation of the magnetron control voltage at the input line frequency of 50-60 Hz and thus to modulate the output frequency of the magnetron +/−30 MHz (0.5%) around the 5.8 GHz center frequency, preventing standing waves and modes from fully forming. Some embodiments may include a line filter, and provide modulation circuitry for specifically modulating the output microwave energy independent of the AC line voltage.) Other embodiments use power supplies that switch the magnetron on/off at different rates or duty cycles to change its output power.

Some embodiments use higher frequency gyrotron or Klystron tube (28 GHz) as a microwave source to further reduce wavelength and thus further increase the microwave power uniformity. Additionally, other embodiments include one or more traveling wave tube (TWT) or other variable frequency microwave (VFM) sources and scan through multiple frequencies to improve the uniformity of the microwave field within the chamber. For example, the frequency can be varied cyclically between 5.58 and 7.0 GHz over 4096 frequency steps, with each step being 260 Hz wide and having a duration of 25 microseconds. More generally, the frequency can be varied +/−5%, 10%, 20% or an even greater percentage round a center frequency. VFM technology would also include shielding around the outer chamber, since the microwave frequency range extends beyond the Industrial-Scientific-Medical (ISM) band.

Wave guides 116C and 116D transport microwave energy from respective microwave signal generators to the interior of outer chamber 112. In the exemplary embodiment, the wave guides, which are purchased as off-the shelf components, are formed of aluminum with an iridite interior coating to further promote uniform distribution of microwave energy throughout the interior of outer chamber 112. Dimension of the waveguides are based on the frequency of the microwave source and determined using conventional microwave engineering techniques.

Coupled to wave guides 116C and 116D, respective isolators 116E and 116F remove reflected microwave energy from the waveguides by transferring this energy to dummy microwave loads within the isolators. (Power that is not absorbed in the chamber will be reflected back into the wave guides.) Each isolator also includes an internal water cooling loop (not shown) to control its temperature.

Couplers 116G and 116H, which are coupled respectively to isolators 116E and 116F, are used to determine not only how much power is entering the exterior chamber though the waveguides, but also how much power is reflected back through the waveguide out of the chamber. The exemplary embodiment monitors reflected power as a process consistency parameter from run to run to detect process failures or to signal maintenance issues.

Inner chamber assembly 120 includes an inner chamber (or process tube) 122, fluid conduits 123 and 124, fluid sources 125, mass-flow controllers 126, a vacuum pump 127, and a gas injection tube 128. Inner chamber 122, which during heating operations is contained within the interior of outer chamber 112, defines a thermal or diffusion processing environment within its interior. In the exemplary embodiment, inner chamber 122, which is made of a substantially microwave transparent material, such as fused quartz, takes the form of an approximately 36-inch-tall, right circular cylinder that has a domed top and a flat bottom with a central opening. Approximate interior diameter of the exemplary cylinder is 16.25 inches (0.413 m.) Some embodiments form the inner chamber from other materials, such as polytetrafluorethylene (PTFE), perfluoralkoxy (PFA), or other material which nominally exhibits a low dielectric loss factor (tan (δ)) at the relevant operating temperature and frequencies. Some embodiments form the chamber from a material having a dielectric loss factor that is less than 0.004 within the operative temperature range of the system. However, other embodiments may use other loss factor values and/or temperature ranges. Some embodiments may also use composites of various materials which individually exhibit low dielectric loss factors to prevent or reduce microwave absorption.

Inner chamber 122 has a lower portion 122A, which includes openings 122B and 122C that are in fluid communication with respective fluid conduits 123 and 124.

Fluid conduit 123, which includes an injector portion 123A, couples opening 122B to fluid sources 125 via mass flow controllers 126. Injector portion 123A extends vertically from opening 122B toward the domed top of inner chamber 120, and has an outlet 123B through which fluid can exit and flow downward over wafer carrier assembly 130 toward opening 122C and vacuum pump 127.

In the exemplary embodiment, outlet 123B is positioned above the highest wafer in fluid sources 125 includes one or more gases, such as oxygen and/or ozone or an oxygen-ozone mixture, to facilitate formation of an oxide layer on a silicon or other material wafer held by wafer carrier assembly 130. Fluid conduit 124 couples opening 122C to vacuum pump 127, which not only functions to evacuate inner chamber 122, but ultimately to establish low-pressure conditions for processing wafers held by wafer carrier assembly 130. In operation, injector portion 123A mixes the air (or other inert or reactive gas) inside inner chamber 122, eliminating and/or managing convection currents in the chamber. Some embodiments include mode stirrers (for example, metal or microwave-reflective fans) or dampers in the outer chamber to further promote or optimize uniform EMW field within the chamber for particular applications.

Wafer carrier assembly 130, which extends up through an opening in the bottom of inner chamber 122, includes a vertical wafer stacking rack (boat) 132, wafers 134, and elevator-rotator assembly 136. Vertical wafer stacking rack 132, which is shown in perspective in FIG. 1D, includes wafer support legs 132A, 132B, 132C, 132D and upper and lower rings 132E and 132F. (Legs 132C and 132D are only visible in FIG. 1D.) Support legs (or vertical members) 132A-132B are attached at their ends to upper and lower rings 132E and 132F. (A reference diameter line 132X is shown on ring 132F, showing that legs 132A and 132B are placed closer to and on a different side of the diameter line than legs 132C and 132D.) The support legs include corresponding sets of 50, 75, or 100, wafer slots, such as representative slots 132G, for securely holding a corresponding number of wafers 134.

In the exemplary embodiment, wafer stacking rack 132 is formed of substantially microwave transparent material, such as fused quartz, and the slot spacing provides a wafer pitch in the range 0.1875-1.00 inches (4.78-25.4 millimeters), inclusive. However, in general, the pitch is dependent on process type, time, wafer size, and temperature; so, other embodiments may use other pitches. Notably, the quartz construction of the exemplary wafer stacking rack provides low thermal mass to promote a substantially constant thermal gradient across each of the wafers. If the thermal mass of the rack is too high, the rack itself will act as a heat sink, not only adversely affecting uniformity of the thermal gradient across each wafer, but also adding thermal mass that dampens the thermal ramping and de-ramping rates of the system. In some embodiments, the wafer stacking rack is formed of composite materials that include quartz and/or other microwave-transparent or non-transparent materials.

Wafers 134 include process wafers 1341, upper and lower baffle or dummy wafers 1342 and 1343, and thermocouple wafer 1344. With the exception of end process wafers 1341A and 1341B, each of the process wafers 1341 lies between an upper and lower process wafer and is thus considered an intermediate process wafer in the wafer stack. For example, process wafer 1341E lies between wafers 1341D and 1341F and is considered an intermediate wafer. (In the figure, the 1341 prefixes are omitted; so, for example, end process wafer 1341A is designated ‘A’.) The upper and lower process wafers, which have substantially identical physical properties and dimensions as the intermediate process wafers, serve as virtual hot plates and/or susceptor plates (microwave loads) for the intermediate wafers. As further described below, the upper and lower process wafers promote not only effective coupling of the microwave energy to the intermediate process wafers, but also uniform temperature gradient across the intermediate process wafers.

Some embodiments replace one or more of the intermediate wafers with other “stacked” objects of different microwave absorbing materials and shapes to obtain similar result. For example, one embodiment replaces every other process wafer with a silicon-carbide disc or plate. Ideally, the microwave-absorbing object has dielectric properties similar to that of the process wafers; however, even objects with different dielectric properties than the process wafers are expected to promote thermal uniformity.

Upper and lower baffle wafers 1342 and 1343, which include one or more wafers, for example three, with substantially identical physical properties and dimensions as the process wafers 1341, serve as virtual hot plates and/or susceptor plates for respective adjacent end process wafers 1341A and 1341B. Additionally, the upper and lower baffle wafers are provided to further ensure that process wafers 1341 lie within a region of inner chamber that exhibits a substantially uniform distribution of microwave energy.

In the exemplary embodiment, each of the process and baffle wafers are substantially identical and consists primarily of a semiconductive material, such as silicon. Silicon couples sufficiently well with 0.90 GHz-28 GHz microwave energy from microwave sources 116A and 116B to enable substantially uniform volumetric (inside-out) heating. (Also, in some embodiments, wafers 134 are glass substrates.) The thickness of each wafer in the exemplary embodiment is in the range of 0.01 inches (0.0254 millimeters) to further promote uniform depth of penetration of the 0.90 GHz-28 GHz microwave energy, and thus even more uniform volumetric heating.

In some embodiments, the wafers include integrated transistors and/or conductive and insulative structures which define one or more integrated circuits, or more generally partial integrated circuits or integrated-circuit assemblies. For example, in various embodiments, each of the process wafers includes an integrated circuit assembly or structure that has a nominal dimension less than or equal to 65 nanometers and/or a trench having an aspect ratio at least as great as 30 to 1. Other embodiments provide the wafers with larger or smaller nominal feature dimensions.

In addition to wafer stacking rack 132 and wafers 134, wafer carrier assembly 130 includes elevator-rotator assembly 136. Assembly 136 includes an electromechanical apparatus (not shown separately) for raising and lowering wafer stacking rack 132 into and out of outer and inner chambers 112 and 122. Additionally, assembly 136 includes an electromechanical rotator apparatus (not shown separately) for rotating wafer stacking rack 132 about a central axis 136A of inner chamber 122. In the exemplary embodiment, the rotator apparatus includes an electric motor coupled via a belt to a pulley, and the pulley is coupled to an axial shaft portion of the wafer carrier assembly. The exemplary embodiment provides a rate adjustable from 1-15 revolutions per minute.

Controller 140 is coupled to thermocouple wafer 1344, to microwave sources 116A and 116B and to couplers 116G and 116H. In the exemplary embodiment, controller 140 takes the form of a proportional-integral-derivative (PID) controller, which receives as a control input a temperature set point, and determines an error signal based on a measured temperature from thermocouple wafer 1344 to the reference setpoint value. The difference (or “error” signal) is then used to calculate a control voltage for the microwave sources that drives microwave output to yield a temperature back to its desired setpoint. The PID controller can adjust process outputs based on the history (and rate of change of the error signal, which generally provides more accurate and stable control than simple proportional control systems which can also be used. Couplers provide power measurements, such as input and reflected power measurements to controller 140. Controller 140 stores the power measurements in addition to responding to them. The reflected power measurements are useful for monitoring process consistency and repeatability from run to run, with significant deviations in reflected power indicating potential equipment defects or maintenance needs. FIG. 1E shows a simplified block diagram of controller 140 interacting with other components of system 100.

In general operation, system 100 introduces 0.90 GHz-28 GHz microwave energy, for example, 5.8 GHz, from microwave sources 116A and 116B into outer chamber 112 via wave guides 116C and 116D, while wafers 134 are rotated. The introduced microwave energy reflects off the obliquely angled interior surfaces of outer chamber 112 and creates a plurality of microwave modalities. The reflective nature of the interior surfaces prevents outer chamber 112 from heating, effecting a cold wall chamber relative to the temperatures of wafers 134 and inner chamber 122. For example, if the wafer temperature is 350 C, the interior and exterior chamber walls will be at the substantially lower temperature within the range of 50-60 C In contrast, the chamber walls of a hot wall chamber will be at approximately the same temperature as the wafers.

After entering the outer chamber, the microwave energy passes through the microwave-transparent material of inner chamber 122 and wafer rack 132 into wafers 134. In some embodiments, the inner chamber includes a microwave absorbing gas, such as argon, neon, helium, krypton, xenon, or other noble gas, which absorbs the microwave energy and evenly heats the wafer stack. The controller regulates the microwave power and/or blower based on sensed temperature to obtain desired temperature-versus-time characteristics. Additionally, in the exemplary embodiment, the controller

### Exemplary Method of Operation

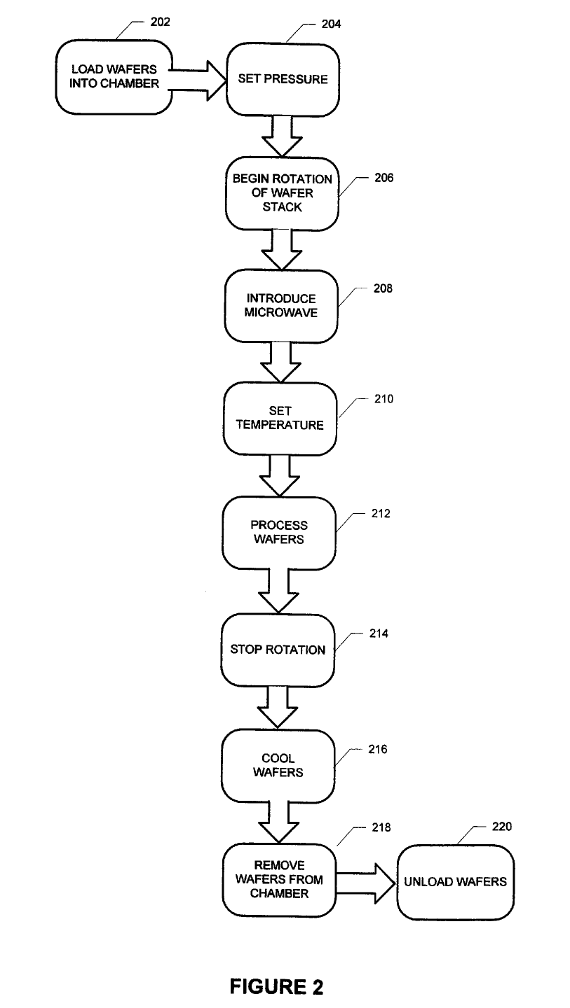

More particularly, FIG. 2 shows a flow chart 200 of one or more exemplary methods of operating system 100. Flow chart 200 includes blocks 202-222, which are arranged and described in a serial sequence in the exemplary embodiment. However, other embodiments may execute two or more blocks in parallel, omit one or more blocks, alter the process sequence, or provide different functional partitions to achieve analogous results. Moreover, still other embodiments implement the blocks in conjunction with two or more interconnected hardware modules and components with related control and data signals communicated between and through the modules or components.

Block 202 entails loading a batch of wafers into the wafer carrier assembly. In the exemplary embodiment, this entails lowering the wafer stacking rack and using a robot to load in the range of 10 to 150 silicon wafers into the vertical rack one wafer over another with half-inch (12.7 millimeters) or alternative spacing between them. The wafer spacing, generally in the range of 0.188″-0.750″ is dependent on the size of the wafers, 150, 200, or 300 millimeters for example. Some embodiment may load fewer than 10 wafers. When the wafer loading is complete, the rack is raised into normal operating position, thereby sealing the inner chamber. Some embodiments lower the wafer stacking rack into the inner chamber; others hold the wafer stack in a fixed position and raise or lower chambers 112 and 122 to enclose the wafer stack; and still others may open and close or separate the chambers longitudinally to allow side or horizontal loading of the wafer stacking rack. Execution continues at block 204.

Block 204 entails establishing the desired pressure conditions for processing the wafers. In the exemplary embodiment, this entails evacuating inner chamber 122 (process tube) using vacuum pump 127. When the desired pressure inside the chamber is reached (for example 10 torr measured by a manometer connected to inner chamber 122), execution continues at block 230. (Some embodiments may also introduce microwave absorbing gas to facilitate subsequent heating. And, some embodiments may also omit pressure control altogether.)

Block 206 entails initiating rotation of the wafer stack. In the exemplary embodiment, this entails activating a motor and manually or automatically setting a variable speed control input associated with elevator-rotator assembly 136 to 1-15 RPM. However, other embodiments may use faster or slower rates of rotations. Execution continues at block 208.

Block 208 entails introducing microwave energy into the outer and inner chambers. In the exemplary embodiment, this entails activating microwave sources 116, for instance four 700 Watt 5.8 GHz magnetrons, which as noted above are powered via unfiltered output of a switch mode power supply, and thus provide a slightly modulated microwave energy, for example +/−30 MHz. This frequency modulation prevents or inhibits standing waves or modes from fully forming. The modulated microwave energy is then transferred through the wave guides into the outer chamber 112 and through inner chamber 120, reflecting off the interior oblique angles of the right octagonal cylinder of outer chamber 112 to define a multimode pattern. A substantially constant mode pattern still remains within the outer chamber but with lower power density; therefore, the range of any resulting temperatures caused by any hot and cold spots is severely compressed.

Block 210 entails establishing the desired wafer temperature. In the exemplary embodiment, the wafer temperature is monitored using a thermocouple wafer and controlled using a closed loop feedback control, which varies the power output of the microwave sources to rapidly obtain the desired process temperature, for example 350 C, or more generally in the range of 50-550 C This temperature is then dynamically maintained throughout the process, with blower 114A operating continuously or intermittently as necessary to manage convection currents in the region between the outer and inner chambers. Notably, the exemplary embodiment minimizes or reduces the input microwave power required to maintain the wafers at the desired temperature by using couplers to monitor microwave power reflected out of chamber 112 and reducing the input power to reduce or minimize this reflected level. This reduces overall power concentrations within the chamber to that which is optimal or near optimal for maintaining the desired temperature of the wafers and thus further reduces any arcing concerns.

Notably, the reflective interior surfaces of outer chamber 112 and the microwave-transparent properties of the inner chamber and wafer stacking rack result in the inner and outer chambers having a cold wall performance characteristic, with the wafers in the wafer stacking rack being the only items heated within the system. (As used herein, cold wall refers to the outer or inner chamber being substantially cooler than the wafer stack, for example, 250-300 degrees cooler. More generally, any chamber wall having a temperature low enough to prevent undesirable reactions with its surface during wafer processing would qualify as cold relative to the wafers.

Moreover, as each wafer in the stack couples with the multimodal microwave energy heats up from the inside-out (that is, volumetrically), it functions as a virtual hotplate for the wafer above and below, promoting a uniform temperature gradient across the two wafers. The low thermal mass of each wafer is significant within the cold wall environment, because the stacked wafer assembly forms a substantially uniform thermal field above and below each wafer, effectively canceling the non-uniform heating effect commonly caused by low power modes of microwave energy.

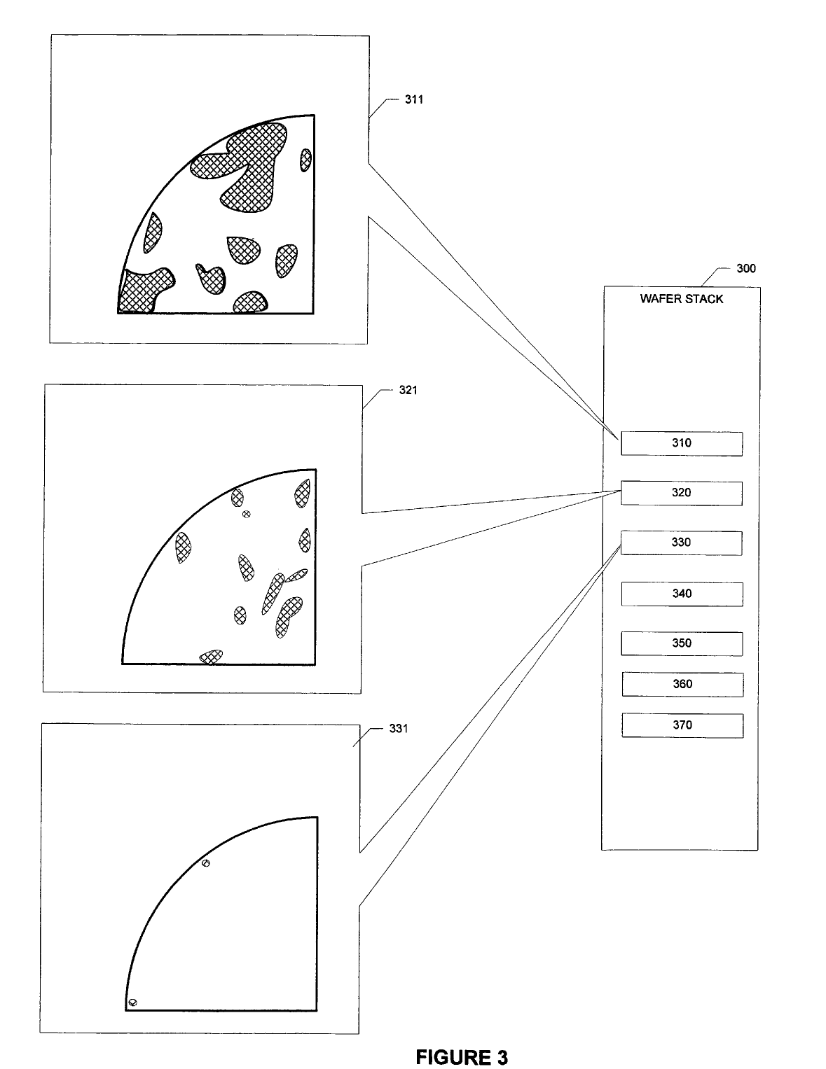

Additionally, each wafer generally experiences or exhibits a unique mode pattern that is dependent on the geometry of the chamber, its position within the chamber, and microwave mode formation within the chamber. With the varying mode patterns, each wafer has minimal or reduced hot and cold spots that tend to balance or offset the hot and cold spots of the wafers above and below it. FIG. 3 shows simplified quarter-sectional microwave power dissipation diagrams 311, 321, and 331, for respective wafers 310, 320, and 330 in a wafer stack 300 that also includes wafers 340, 350, 360, and 370.

In this example, dissipation diagram 311 for wafer 310, the top wafer, includes numerous regions of relatively high power dissipation, called hot spots, because there is no wafer above wafer 310. The hot spots are denoted by the cross-hatched regions, with the remaining portions of the wafer exhibiting substantially lower power dissipation levels. Wafer 320 benefits from having wafer 310 above it to serve as a susceptor plate and thus its dissipation diagram 321 exhibits hot spots of substantially diminished total area than wafer 310. Wafer 330 benefits from having wafers 310 and 320 above and therefore its dissipation diagram 331 exhibits minor if not negligible hot spots.

Although power dissipation diagrams for wafers 340-370 are not shown, the degree of hot spotting for these wafers can be inferred from similarly situated wafers in the stack. Wafers 340 and 350 for instance each have at least two wafers above them and two wafers below them, thus the occurrence of hot spots is similar to that of wafer 330. Wafers 350 and 360, on the other hand, are respectively analogous to wafers 320 and 310 and therefore exhibit similarly increased hot spotting. Overall, FIG. 3 not only illustrates the benefits of stacking the wafers, but also the benefit of providing baffle wafers at the ends of the wafer stack.

In the exemplary embodiment, the temperature gradient is substantially uniform across each wafer as well as uniform across the stack (+/−5 deg C.). To further optimize temperature uniformity, the wafer stack is rotated within the chamber during heating. This will change the mode patterns seen by each wafer, further optimizing temperature uniformity. The top and bottom wafer in the stack are used as baffle wafers and temperature uniformity is not critical here because the wafers targeted for thermal treatment are all in between. Some embodiments use a variable frequency microwave energy, which cycles between 5 and 7 GHz in 4096, 25-microsecond frequency steps. More generally, the frequency may be varied a percentage amount such +/−5, 10, 15, 20, or even more about a center frequency or cycle scanned from the minimum frequency to the maximum frequency of the range. Exemplary execution continues at block 212.

Block 212 entails processing the wafers. In the exemplary embodiment, this processing entails curing, annealing, and/or forming one or more films of the wafers. Curing and annealing generally entail maintaining the wafers at the desired temperature(s) for a specific period of time.

In one exemplary curing process, one or more of the loaded wafers include one or more polyimide, epoxy, or benzocyclobutene (BCB) structures. Notably, fully cured polymeric films or structures become transparent to microwaves and thus allow curing to continue below the surface of the polymeric films, in contrast to conventional resistive heat curing where the polymeric films are thermal barriers.

In one exemplary annealing process, one or more of the wafers includes a metallic structure, such as a copper conductor, which is entrenched at a high aspect ratio, for example, 10, 20, or 30 to 1. Materials entrenched at high aspect ratios have been difficult to heat using conventional outside-in heating techniques. Other embodiments anneal low-dielectric-constant (low-K) dielectrics, high-dielectric-constant (high-K) dielectrics, or silicon-on-insulator structures.

Forming a film or material layer generally entails introducing one or more fluids (liquids or gases) into inner chamber 122. To this end, the exemplary embodiment actuates fluid sources 125, which is in fluid communication with chamber 122 via conduit 123 and gas injector 123A. In one embodiment, fluid sources 125 take the form of a commercially available ozone generator, which provides a mixture of oxygen and 10% or 25% ozone (by volume). Other embodiment may use concentrations less than 75%, such as 70%, 60%, 50%, 40%, and 30%. Some embodiment introduces other gases, such as nitrogen, to form other materials, such as silicon nitride (Si₃N₄), at atomic-level thicknesses.

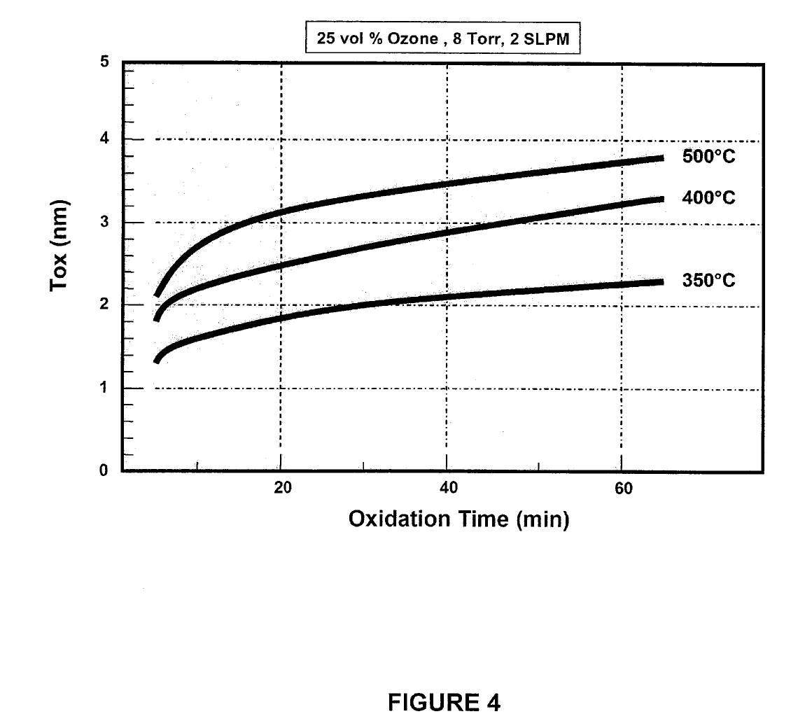

The gas injector transports the gas to the top of the wafer stack and the gas is pulled over the wafers and out of the inner chamber via vacuum pump 127, reacting with the exposed surfaces of each of the wafers and forming a material layer, such as silicon oxide. The flow is continued for a period of time dependent on the desired thickness of the layer (silicon oxide) and the pressure and temperature settings. The inner chamber is cold (approximately 50 C); thus, the fluid, for example ozone, reacts only with the wafers, which are at 350 C, and forms a thin dense silicon dioxide film, which is widely used as a high quality insulator for semiconductor devices. Generally, the amount of time to obtain a desired film thickness under given pressure and conditions is determined experimentally. FIG. 4 shows an oxide thickness (Tox) versus oxidation time for three different process temperatures, 350, 400, and 500 C, using a 25% ozone concentration. Formation of the material layer is terminated by shutting off fluid flow and evacuating the inner chamber. Execution continues at block 214.

Block 214 entails terminating rotation of the wafers. To this end, the exemplary embodiment manually or automatically shuts off a motor portion of elevator-rotator assembly 136. Exemplary execution continues at block 216.

Block 216 entails cooling the wafers within inner chamber 122. In the exemplary embodiment, this entails deactivating the microwave energy sources, and activating recirculation blowers 114A to accelerate heat transfer across the walls of inner chamber 122 to the interior of outer chamber 112. In contrast to this exemplary in-chamber cooling, conventional batch wafer heaters remove the wafers to a zero-oxygen clean room, where it may take several hours for the wafers to cool to room temperature. When the temperature of the wafers falls below 50 C or some other desired threshold, typically less than an hour, execution proceeds to block 218.

In block 218, the cooled wafer stack is removed. In the exemplary embodiment, removal of the wafers entails using elevator-rotator assembly 136 to lower the loaded wafer carrier from inner chamber 122 and consequently outer chamber 112 as well. Notably, the wafers are lowered into a conventional clean room environment which includes typical levels of atmospheric oxygen.

Block 220 entails unloading the wafers from wafer stacking rack 132. In the exemplary embodiment, all of the wafers except for the baffle wafers are removed using a robot. In some embodiments, the wafer stacking rack and the wafers are removed and transported to another processing station.

The systems and methods described above are generally believed to be well suited to any application that can benefit from uniform low-temperature heating of substrates. For example, the inventors contemplate that the apparatus and/or methods described herein are applicable to aluminum sintering, H2 annealing, SiLK annealing, baking and reflowing of photoresist, radical oxidation and nitridation, ultra low temperature low pressure chemical vapor deposition (LPCVD) (nitride for example), and ultra thin gate dielectric formation.

### CONCLUSION

In furtherance of the art, the present inventors have devised and presented herein, among other things, systems, methods, and components that, among other things, use multimodal microwave energy, to facilitate rapid and uniform thermal treatment of silicon wafers or integrated-circuit assemblies. One exemplary system includes an outer chamber for containing microwave energy, a microwave-transparent pressure chamber within the outer chamber for maintaining pressure and containing fluids, and a microwave-transparent wafer stack assembly within the inner chamber. The outer chamber evenly distributes multimodal electromagnetic energy, for example multimode 5.8 GHz energy, over silicon wafers in the wafer stack assembly. The silicon wafers are heated volumetrically and substantially uniformly, whereas the microwave-transparent inner chamber and wafer stack assembly are heated very little, if at all. Baffle wafers are included in the wafer stack to promote uniform processing of adjacent wafers that would otherwise be exposed to regions with unacceptable hot spot concentrations. The exemplary microwave systems and methods hold the promise of reducing thermal process times and lowering conventional process temperatures, all while maintaining equal or better process results.

The embodiments described above are intended only to illustrate and teach one or more ways of making and using the present invention, not to restrict its breadth or scope. The actual scope of the invention, which embraces all ways of practicing or implementing the teachings of the invention, is defined only by one or more issued patent claims and their equivalents.

1. Apparatus comprising:
a first chamber;
at least one nominal 5.8 Gigahertz microwave signal generator coupled to introduce microwave energy into the first chamber; and
a wafer-stacking rack contained within the chamber for holding a plurality of silicon wafers, with the rack consisting essentially of a substantially microwave-transparent material.

2. The apparatus of claim 1, wherein the microwave signal generator is ISM compliant.

3. The apparatus of claim 1:
wherein the first chamber has at least one dimension that is greater than a wavelength of the microwave energy; and
wherein the first chamber includes a plurality of at least five microwave-reflective sidewalls for containing and reflecting the microwave energy.

4. The apparatus of claim 1, wherein the microwave energy has a time variant frequency range of 5.8 Gigahertz +/−30 Megahertz.

5. The apparatus of claim 1, further comprising a second chamber containing the first chamber, wherein the first chamber comprises a substantially microwave-transparent material and the second chamber comprises substantially microwave-reflective sidewalls.

6. The apparatus of claim 1, wherein the wafer-stacking rack is configured to support and uniformly space at least 25 wafers in a vertical stack.

7. The apparatus of claim 1, wherein the wafer-stacking rack comprises at least two annular members and at least vertical members extending vertically between the two annular members.

8. The apparatus of claim 1, comprising at least two or more nominal 5.8-Gigahertz microwave signal generators, with the microwave signal generators coupled to introduce microwave energy into the first chamber at different ports.

9. Apparatus comprising:
a microwave-reflective chamber;
a substantially microwave-transparent chamber within the microwave-reflective chamber;
a substantially microwave-transparent wafer rack contained within the microwave-transparent chamber for holding a plurality of silicon wafers in a vertical arrangement; and
at least one nominal 5.8-Gigahertz microwave signal generator coupled to introduce microwave energy into the microwave-reflective chamber to heat the plurality of silicon wafers.

10. The apparatus of claim 9:
wherein the microwave reflective chamber has at least one dimension that is greater than a wavelength of the microwave energy; and
wherein the first chamber includes a plurality of at least five microwave-reflective sidewalls for containing and reflecting the microwave energy.

11. The apparatus of claim 9, wherein the wafer rack is configured to support and uniformly space at least 25 wafers in a vertical stack.

12. The apparatus of claim 9, wherein the microwave-transparent chamber and the wafer rack consist essentially of quartz.

13. The apparatus of claim 9, further comprising recirculation means for recirculating fluid from a higher interior region of the microwave-reflective chamber to a lower interior region of the microwave-reflective chamber.

14. The apparatus of claim 9, wherein the microwave-reflective chamber includes an interior surface, with the interior surface including an iridite coating.

15. The apparatus of claim 9, further comprising a mass-flow controller for coupling to a fluid source, and a fluid injector in fluid communication with the mass-flow controller and positioned within the microwave-transparent chamber.

16. The apparatus of claim 9, comprising two or more nominal 5.8-Gigahertz microwave signal generators, with the microwave signal generators coupled to introduce microwave energy into the microwave-reflective chamber at different ports.

17. Apparatus comprising:
a rack for supporting a plurality of silicon wafers in a vertical stack arrangement;
a first chamber for enclosing the rack;
a second chamber for enclosing the first chamber;
at least one nominal 5.8-Gigahertz microwave signal generator coupled to introduce microwave energy into the microwave-reflective chamber to heat the plurality of silicon wafers; gas-injecting means for conveying fluid into the first chamber.

18. The apparatus of claim 17, further comprising means for moving the rack into and out of the first chamber means.

19. The apparatus of claim 17, further comprising recirculation means for recirculating fluid from a higher interior region of the second chamber to a lower interior region of the second chamber.

20. The apparatus of claim 17, wherein the second chamber includes a plurality of at least five microwave-reflective sidewalls for containing and reflecting the microwave energy.

21. The apparatus of claim 17, wherein the first chamber and the rack consist essentially of quartz.

22. The apparatus of claim 17, wherein the rack consist essentially of a microwave-transparent material and is configured to support at least 50 wafers in a vertical stack arrangement.

23. The apparatus of claim 17, comprising two or more nominal 5.8-Gigahertz microwave signal generators, with the microwave signal generators coupled to introduce microwave energy into the microwave-reflective chamber at different ports.

24. A method of heating two or more silicon wafers, the method comprising:
arranging the silicon wafers in a vertical stack; and
irradiating the vertical stack of silicon wafers using multimodal microwave energy from at least one nominal 5.8 GHz microwave source.

25. The method of claim 24, wherein irradiating the vertical stack of silicon wafers using the multimodal microwave energy, comprises exposing the vertical stack of wafers to microwave energy reflected off of at least 5 sidewalls of a chamber enclosing the vertical stack.

26. The method of claim 24, wherein irradiating the vertical stack of silicon wafers using the multimodal microwave energy comprises modulating frequency of a 5.8-GHz magnetron.

27. The method of claim 24, wherein irradiating the vertical stack of silicon wafers comprises volumetrically heating the wafers to a thermal uniformity of one degC/wafer or better.

28. The method of claim 24, wherein two or more of the wafers include integrated circuit structures having a nominal dimension of 65 nanometers or less.

29. A method comprising:
arranging a plurality of silicon wafers in a vertical stack; and
irradiating the vertical stack of silicon wafers using multimodal microwave energy to achieve a desired temperature; and
exposing the vertical stack of silicon wafers to a concentration of ozone that is less than 90% by volume for a select period of time to form an oxide layer on each of the wafers.

30. The method of claim 29, wherein irradiating the vertical stack of silicon wafers comprising containing the vertical stack of wafers within a microwave-transparent chamber that is contained within a microwave-reflective chamber.

31. The method of claim 29, wherein the vertical stack of silicon wafers includes at least 25 wafers.

32. The method of claim 29, wherein irradiating the plurality of silicon wafers comprises outputting microwave energy from at least two microwave sources.

33. A method comprising microwaving a plurality of silicon wafers using multimodal microwave energy wherein the energy is reflected off at least 5 substantially vertical sidewalls of a chamber enclosing the wafers.

34. The method of claim 33, further comprising arranging the plurality of silicon wafers into a vertical stack prior to microwaving the plurality.

35. The method of claim 34, wherein arranging the plurality of silicon wafers into a vertical stack includes arranging the wafers such that each wafer has at least one wafer above and one wafer below the wafer, and spacing the wafers such that one wafer above and the one wafer below acts as a susceptor plate to promote uniform heating of the wafer.

36. The method of claim 33, further comprising rotating the vertical stack of wafers while microwaving.

37. The method of claim 33, wherein the wafers are enclosed in a chamber that has a temperature at least 50 C lower than that of the wafers while microwaving.
